(19) United States
(12) Patent Application Publication
(10) Pub. No.: US 2026/0136639 A1
(43) Pub. Date: May 14, 2026

(54) DIELECTRIC LINERS ALONG SIDEWALLS OF ISOLATION FEATURE IN STACKED TRANSISTORS AND METHODS OF FORMING THE SAME

(71) Applicant: Taiwan Semiconductor Manufacturing Co., Ltd., Hsinchu (TW)

(72) Inventors: Guan-Ren Wang, Hsinchu (TW); Chun-Yu Liu, New Taipei City (TW); Min-Chang Tsai, Tainan City (TW)

(21) Appl. No.: 19/089,378

(22) Filed: Mar. 25, 2025

Related U.S. Application Data
(60) Provisional application No. 63/720,514, filed on Nov. 14, 2024.

(51) Int. Cl. H10D 84/01; H10D 84/83

(52) U.S. Cl. CPC H10D 84/0153; H10D 84/832

(57) ABSTRACT

A semiconductor device and the method of forming the same are provided. The semiconductor device may include a first source/drain region, a first nanostructure on a first sidewall of the first source/drain region, a first gate structure around the first nanostructure, a first inner spacer on the first sidewall of the first source/drain region, a second inner spacer on a second sidewall of the first source/drain region, a first dielectric liner on a sidewall of the second inner spacer, and a first isolation feature on a sidewall of the first dielectric liner. The first inner spacer may be between the first gate structure and the first source/drain region. The second inner spacer may be between the first dielectric liner and the first source/drain region. The first dielectric liner may be between the first isolation feature and the second inner spacer.

### PRIORITY CLAIM AND CROSS-REFERENCE

This application claims the benefit of U.S. Provisional Application No. 63/720,514, filed on Nov. 14, 2024, which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example a stacking transistor in accordance with some embodiments.

FIGS. 2, 3, 4, 5A, 5B, 5C, 6A, 6B, 6C, 7A, 7B, 8A, 8B, 9A, 9B, 10A, 10B, 11A, 11B, 11C, 12, and 13 are various views of intermediate stages in the manufacturing of a stacking transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor device and methods of forming the same. The semiconductor device may be a stacking transistor comprising an upper transistor and a lower transistor that are vertically stacked. Each of the upper and lower transistors may include gate structures wrapping around respective semiconductor nanostructures and source/drain regions on sidewalls of the respective semiconductor nanostructures. In certain regions of the semiconductor device, isolation features may extend through the upper transistor and the lower transistor. Before the formation of the isolation features, dielectric liners may be formed in the upper transistor to protect the source/drain regions in the upper transistor during various etching processes, which may create openings for the formation of the isolation features. As a result, the performance and reliability of the stacking transistor may be improved.

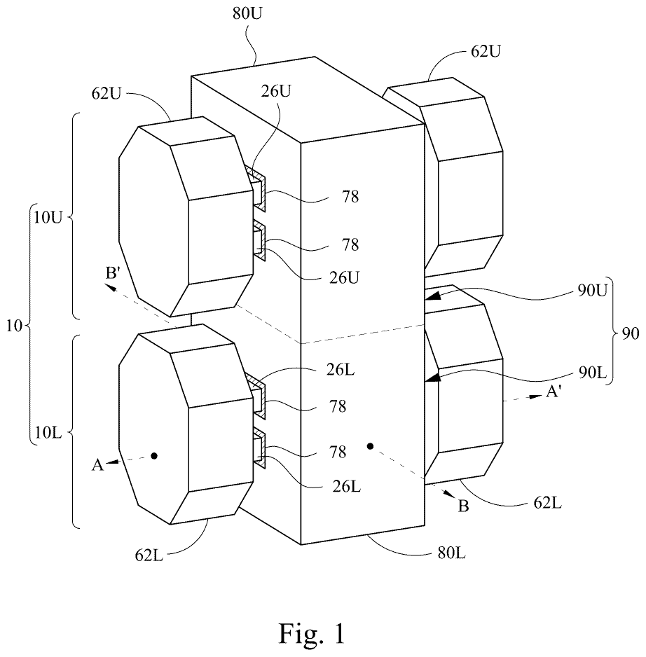

FIG. 1 illustrates an example of a stacking transistor 10 in accordance with some embodiments. FIG. 1 is a perspective view, and some features of the stacking transistor are omitted for illustration clarity. The stacking transistor includes multiple vertically stacked FETs. For example, a stacking transistor may include a lower nanostructure-FET 10L of a first device type (e.g., n-type or p-type) and an upper nanostructure-FET 10U of a second device type (e.g., p-type or n-type). When the stacking transistor is a Complementary Field-Effect Transistors (CFET), the second device type of the upper nanostructure-FET 10U is opposite to the first device type of the lower nanostructure-FET 10L. The upper nanostructure-FETs 10U and lower nanostructure-FET 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors, Nano Field-effect Transistors (nano-FETs), Fin Field Effect Transistors (finFETs), or the like.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate selected ones of the source/drain regions 62 and/or selected ones of the gate electrodes 80.

FIG. 1 further illustrates reference cross-section A-A′ and B-B′. Reference cross-section A-A′ may be a vertical cross-section that is parallel to a longitudinal axis of the semiconductor nanostructures 26 of the stacking transistor 10 and in a direction of, for example, a current flow between the source/drain regions 62 of the stacking transistor 10. Reference cross-section B-B′ may be a vertical cross-section that is perpendicular to the reference cross-section A-A′ and extend through the gate electrodes 80. The reference cross-sections A-A′ and B-B′ in FIG. 1 may correspond to the reference cross-sections A-A′ and B-B′ shown in some of the subsequent top-down view figures.

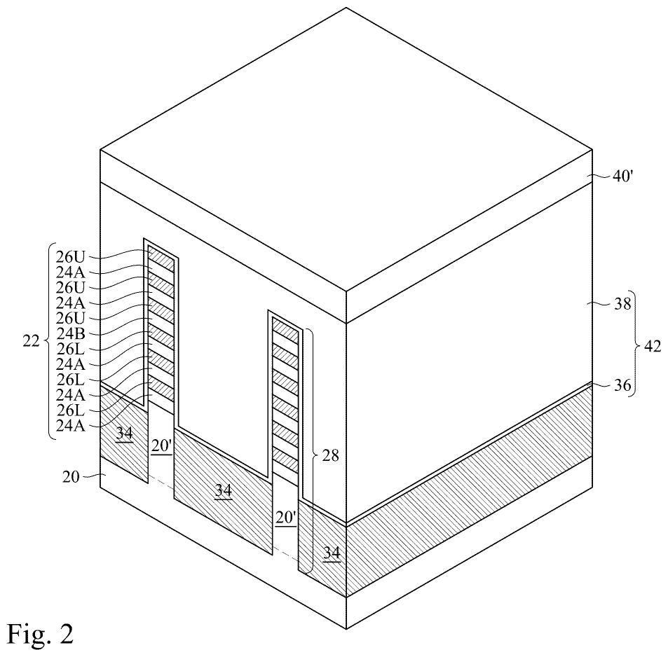

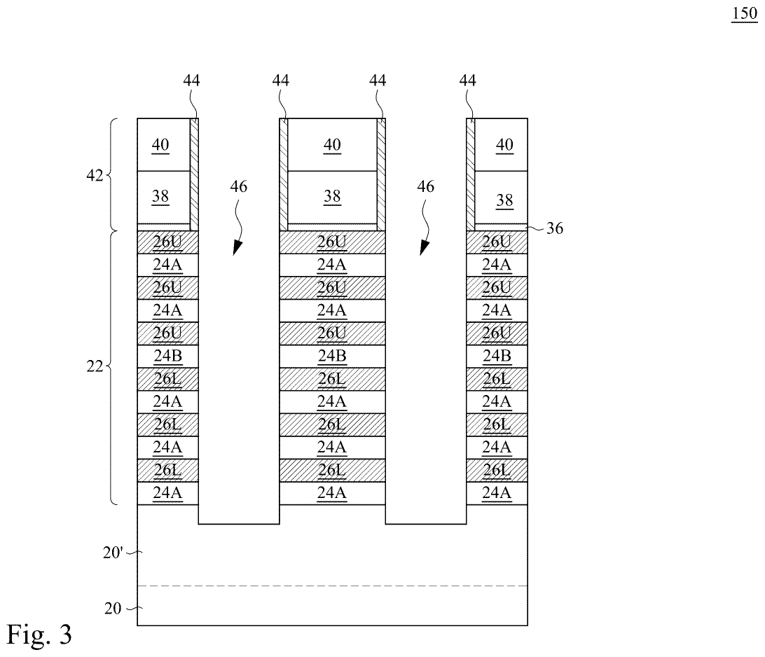

FIGS. 2 through 13 are various views of intermediate stages in the manufacturing of a stacking transistor including lower nanostructure-FETs and upper nanostructure-FETs, which may be similar to the stacking transistor 10 shown in FIG. 1, in accordance with some embodiments. FIG. 2 is a perspective view and FIGS. 3 through 13 are cross-sectional views and top-down views of a portion of the structure shown in FIG. 2. In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor, the like, or combinations thereof.

Semiconductor strips 28 are formed extending upwards from the substrate 20. Each of semiconductor strips 28 includes semiconductor fin 20′ (patterned portions of the substrate 20) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent processes without significantly removing the semiconductor nanostructures 26. In some embodiments, the semiconductor nanostructures 26 are formed of silicon, the dummy nanostructures 24A are formed of silicon germanium, and the dummy nanostructures 24B are formed of germanium or silicon germanium with a higher germanium atomic percentage than the dummy nanostructures 24A.

The lower semiconductor nanostructures 26L may act as channel regions for lower nanostructure-FETs of the stacking transistor. The upper semiconductor nanostructures 26U may act as channel regions for upper nanostructure-FETs of the stacking transistor. The semiconductor nanostructures 26 that are immediately above/below (e.g., in contact with) the dummy nanostructures 24B may be used for isolation and may or may not act as channel regions for the stacking transistor. The dummy nanostructures 24B may be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the substrate 20 to define the semiconductor strips 28, which includes the semiconductor fins 20′, the dummy nanostructures 24, and the semiconductor nanostructures 26.

For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the substrate 20. The etching may be performed by any acceptable etch process, such as a Reactive Ion Etch (RIE), Neutral Beam Etch (NBE), the like, or a combination thereof. The etching may be anisotropic.

STI regions 34 are formed over the substrate 20 and between adjacent semiconductor strips 28. The STI regions 34 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 34 may include depositing the dielectric layer(s), and performing a planarization process such as a Chemical Mechanical Polishing (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 34 include silicon oxide formed by an FCVD process, followed by an anneal process. Then, the dielectric liner and the dielectric material are recessed to define the STI regions 34, such that upper portions of semiconductor strips 28 (including multi-layer stacks 22) protrude higher than the remaining STI regions 34.

After the STI regions 34 are formed, dummy gate stacks 42 may be formed over and along sidewalls of the upper portions of the semiconductor strips 28 (the portions that protrude higher than the STI regions 34). Forming the dummy gate stacks 42 may include forming dummy dielectric layer 36 on the semiconductor strips 28 and forming a dummy gate layer 38 over the dummy dielectric layer 36. Dummy dielectric layer 36 may be formed of, for example, silicon oxide, silicon nitride, a combination thereof, or the like, and may be deposited or thermally grown according to acceptable techniques. The dummy gate layer 38 may be deposited, for example, through Physical Vapor Deposition (PVD), CVD, or other techniques, and then planarized, such as by a CMP process. The material of dummy gate layer 38 may be selected from a group including amorphous silicon, polycrystalline-silicon (polysilicon), poly-crystalline silicon-germanium (poly-SiGe), or the like.

A mask layer 40′ is formed over the planarized dummy gate layer 38. The mask layer 40′ may comprise, silicon nitride, silicon oxynitride, or the like. Then the mask layer 40′ may be patterned by suitable photolithography and etching processes to form a mask 40 (shown FIG. 3), which may be then used to pattern dummy gate layer 38 and the dummy dielectric layer 36. The mask 40, the remaining portions of the dummy gate layer 38, and the dummy dielectric layer 36 may be referred to as the dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. The mask 40, and the gate spacers 44 may be used to protect the dummy gate layers 38 during subsequent etching processes.

Subsequently, source/drain recesses 46 are formed in semiconductor strips 28. The source/drain recesses 46 are formed through etching, and may extend through the multi-layer stacks 22 and into the semiconductor fins 20'. The bottom surfaces of the source/drain recesses 46 may be at a level above, below, or level with the top surfaces of the STI regions 34 (not shown). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a selected depth.

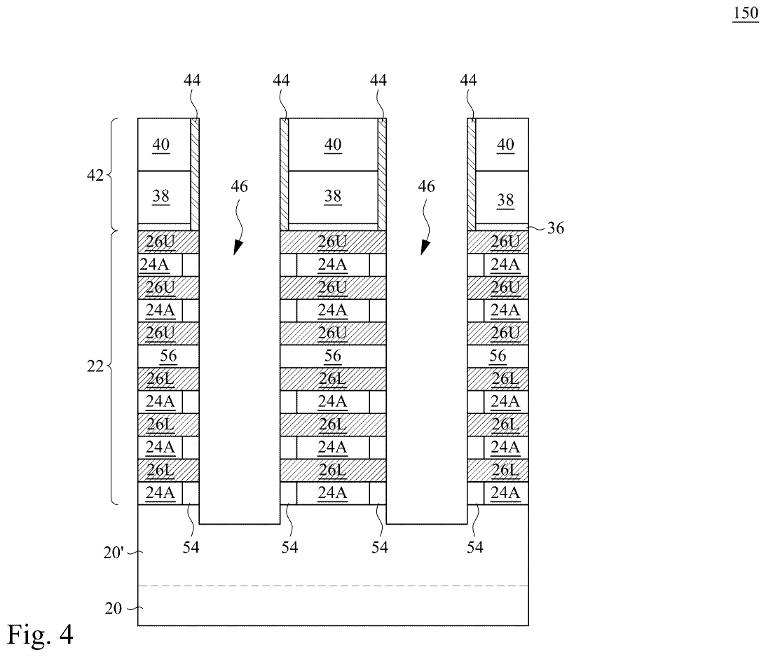

In FIG. 4, the dummy nanostructures 24A are partially removed and the dummy nanostructure 24B are completely removed. Then inner spacers 54 and dielectric isolation layers 56 are formed. After the dummy nanostructures 24A are partially removed, sidewalls of the dummy nanostructures 24A may be recessed. The dummy nanostructures 24A and the dummy nanostructure 24B may be removed by a suitable etching process. The etching process may selectively remove the materials of the dummy nanostructures 24A and the dummy nanostructure 24B without significantly removing the materials of the upper semiconductor nanostructures 26U, the lower semiconductor nanostructures 26L, or the semiconductor fins 20'. The etching process may remove the dummy nanostructures 24A at a slower rate than the dummy nanostructure 24B.

In the embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etching process may be a dry etching process using etchant(s), such as chlorine, and/or the like. Because the dummy gate stacks 42 warp around the sidewalls of the semiconductor nanostructures 26 (see FIG. 2), the dummy gate stacks 42 may support the upper semiconductor nanostructures 26U so that the upper semiconductor nanostructures 26U do not collapse upon the complete removal of the dummy nanostructures 24B.

The inner spacers 54 may be formed on the recessed sidewalls of the dummy nanostructures 24A. The dielectric isolation layers 56 may be formed in spaces the dummy nanostructures 24B occupied before being removed. Source/drain regions may be subsequently formed in the source/drain recesses 46, and the dummy nanostructures 24A may be replaced with corresponding gate structures. The inner spacers 54 may be used to isolate the subsequently formed source/drain regions from the subsequently formed gate structures. The dielectric isolation layers 56 may be used to isolate the upper semiconductor nanostructures 26U from the lower semiconductor nanostructures 26L.

The inner spacers 54 and the dielectric isolation layers 56 may be formed by conformally depositing a suitable dielectric material in the source/drain recesses 46, on the sidewalls the dummy nanostructures 24A, and between the bottom upper semiconductor nanostructures 26U and the top lower semiconductor nanostructures 26L. The dielectric material may be then etched to remove excess portions. The dielectric material may be a hard dielectric material, such as a carbon-containing dielectric material, such as silicon oxycarbonitride, silicon oxycarbide, silicon carbonitride, or the like. Other low-dielectric constant (low-k) materials having a k-value less than about 3.5 may be utilized. The dielectric material may be formed by a suitable deposition process, such as ALD, CVD, or the like. The etching of the dielectric material may be an anisotropic etching process or an isotropic etching process.

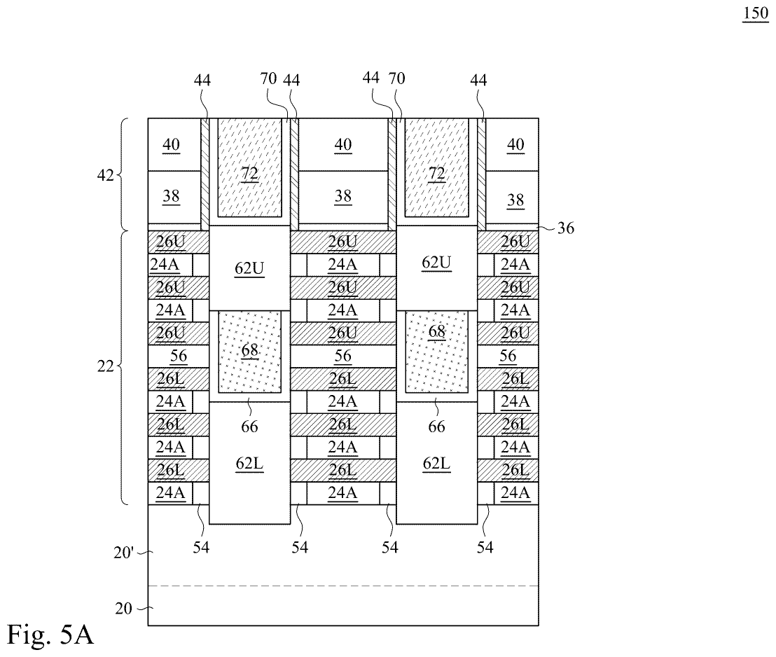

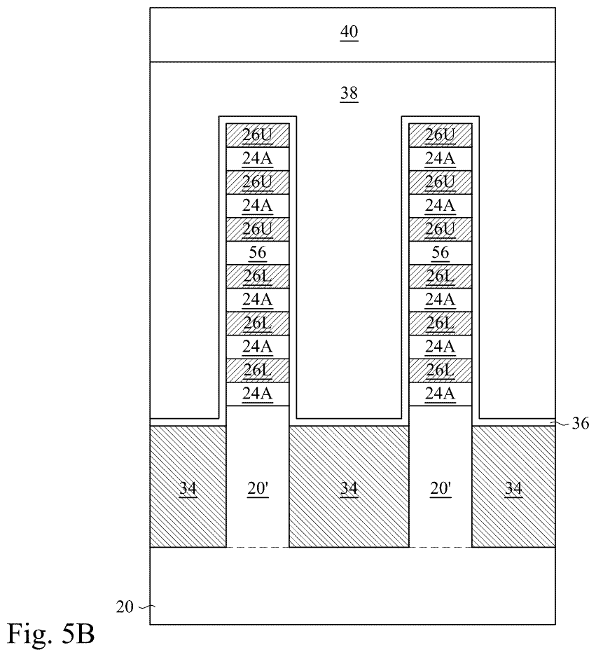

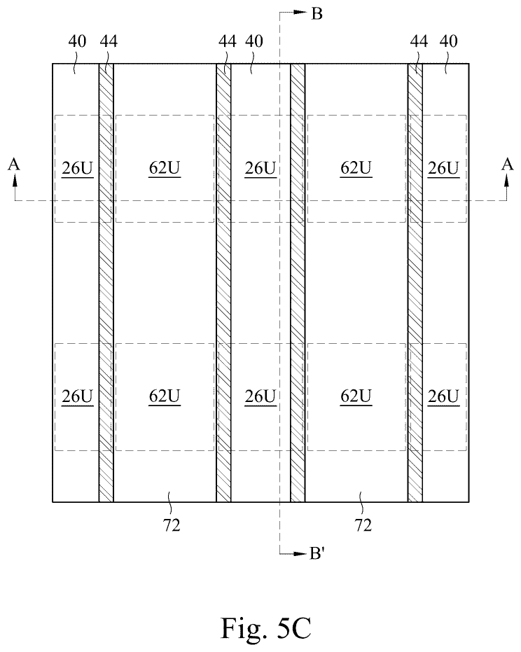

In FIGS. 5A, 5B, and 5C, lower source/drain regions 62L, upper epitaxial source/drain regions 62U, first contact etch stop layers (CESLs) 66, first inter-layer dielectrics (ILDs) 68, second CESLs 70, and second ILDs 72 are formed in the source/drain recesses 46. FIG. 5C is a top-down view with certain features omitted and certain features shown in dashed lines for illustrative purposes. The reference cross-sections A-A′ and B-B′ shown in FIG. 5C may correspond to the reference cross-sections A-A′ and B-B′ shown in FIG. 1. FIG. 5A is a cross-sectional view along the reference cross-section A-A′ as shown in FIG. 5C. FIG. 5B is a cross-sectional view along the reference cross-section B-B′ as shown in FIG. 5C.

The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The upper epitaxial source/drain regions 62U are in contact with the upper semiconductor nanostructures 26U and are not in contact with the lower semiconductor nanostructures 26L. The lower epitaxial source/drain regions 62L are in contact with the inner spacers 54, which electrically insulate the lower epitaxial source/drain regions 62L from the dummy nanostructures 24A. The upper epitaxial source/drain regions 62U are in contact with inner spacers 54, which electrically insulate the upper epitaxial source/drain regions 62U from the dummy nanostructures 24A. The dummy nanostructures 24A will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L to merge.

The first CESLs 66 and the first ILDs 68 are formed over the lower epitaxial source/drain regions 62L. The first CESLs 66 may be formed of a dielectric material having a high etching selectivity from the etching of the first ILDs 68, such as silicon nitride, silicon oxide, silicon oxynitride, or the like, which may be formed by any suitable deposition process, such as CVD, ALD, or the like. The first ILDs 68 may be formed of a dielectric material, which may be deposited by any suitable method, such as CVD, plasma-enhanced CVD (PECVD), or FCVD. The applicable dielectric material of the first ILDs 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILDs 68, followed by a planarization process and then an etch-back process. In some embodiments, the first ILDs 68 are etched first, leaving the conformal CESL layer unetched. An anisotropic etching process is then performed to remove the portions of the conformal CESL layer higher than the recessed first ILDs 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower epitaxial source/drain regions 62L, depending on the selected conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant.

As a result of the epitaxy processes used for forming the upper epitaxial source/drain regions 62U, upper surfaces of the upper epitaxial source/drain regions 62U have facets which expand laterally outward beyond sidewalls of the multi-layer stacks 22. In some embodiments, adjacent upper epitaxial source/drain regions 62U remain separated after the epitaxy process is completed. In other embodiments, these facets cause neighboring upper epitaxial source/drain regions 62U to merge.

After the upper epitaxial source/drain regions 62U are formed, second CESLs 70 and second ILDs 72 are formed. The materials and the formation methods may be similar to the materials and the formation methods of the first CESLs 66 and the first ILDs 68, respectively. The formation process may include depositing the conformal CESL layer and the second ILDs 72, and performing a planarization process to remove the excess portion of the corresponding layers. After the planarization process, top surfaces of the second ILDs 72, the gate spacers 44, and mask 40 are substantially coplanar (within process variations). In the illustrated embodiment, the mask 40 remain after the removal process. In other embodiments, the mask 40 are removed such that the top surfaces of the dummy gate layers 38 are exposed.

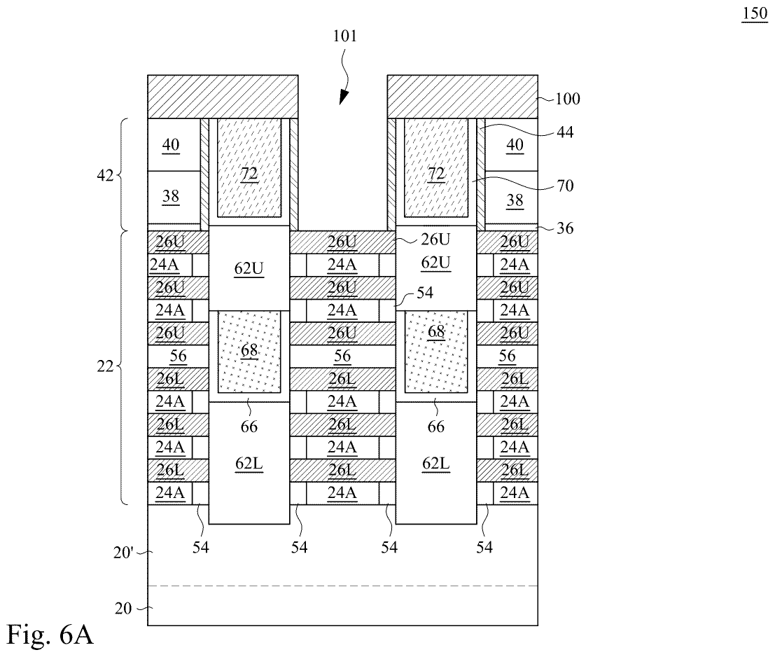

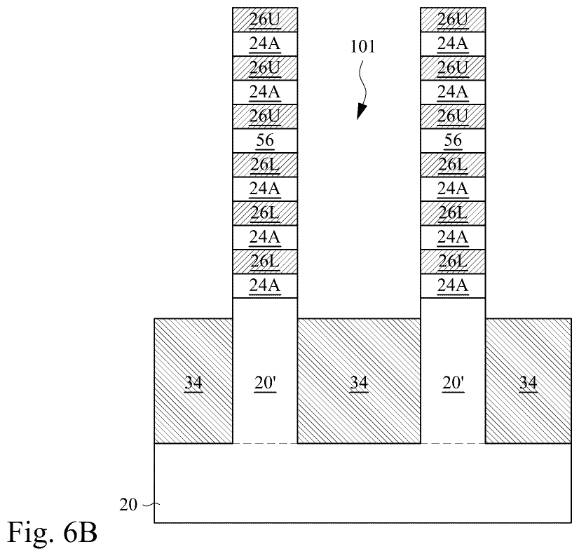

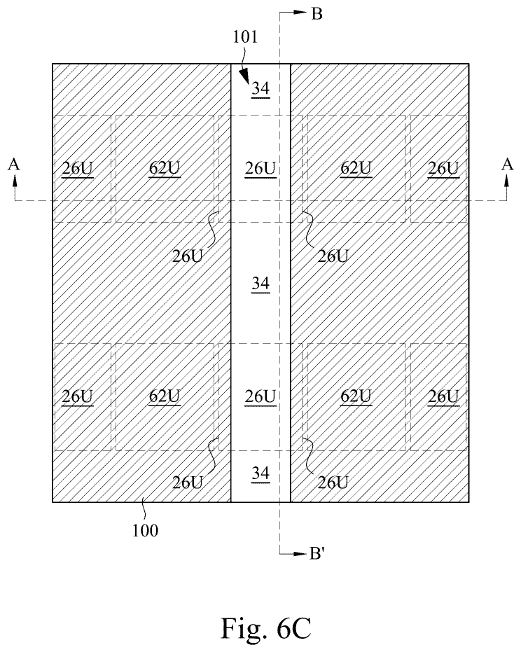

In FIGS. 6A, 6B, and 6C, a mask 100 is formed and an opening 101 is formed using the mask 100 to expose top surfaces of selected upper semiconductor nanostructures 26U and selected portions of the STI regions 34. FIG. 6C is a top-down view with certain features shown in dashed lines for illustrative purposes. The reference cross-sections A-A′ and B-B′ shown in FIG. 6C may correspond to the reference cross-sections A-A′ and B-B′ shown in FIG. 5C. FIG. 6A is a cross-sectional view along the reference cross-section A-A′ as shown in FIG. 6C. FIG. 6B is a cross-sectional view along the reference cross-section B-B′ as shown in FIG. 6C.

The mask 100 may be formed of a suitable dielectric material and formed by suitable deposition and patterning methods. The opening in the mask 100 may expose a selected portion of the mask 40. The opening 101 may be formed by removing the exposed portion of the mask 40, and portions of dummy gate layer 38 and the dummy dielectric layer 36 underneath the exposed portion of the mask 40 by one or more etching processes. The exposed portion of the mask 40 may be removed by a dry etching process using fluorine based plasma as etchants. Then the exposed portion of the dummy gate layer 38 may be removed by one or more dry etching processes using chlorine or bromine based plasma as etchants. Then the exposed portion of the dummy dielectric layer 36 may be removed by a wet etching process using hydrofluoric acid, ammonium hydroxide, or the like as etchants. After the opening 101 is formed, the top surfaces of the selected upper semiconductor nanostructures 26U and the selected portions of the STI regions 34 as well as sidewalls of corresponding gate spacers 44 and multi-layer stacks 22 are exposed.

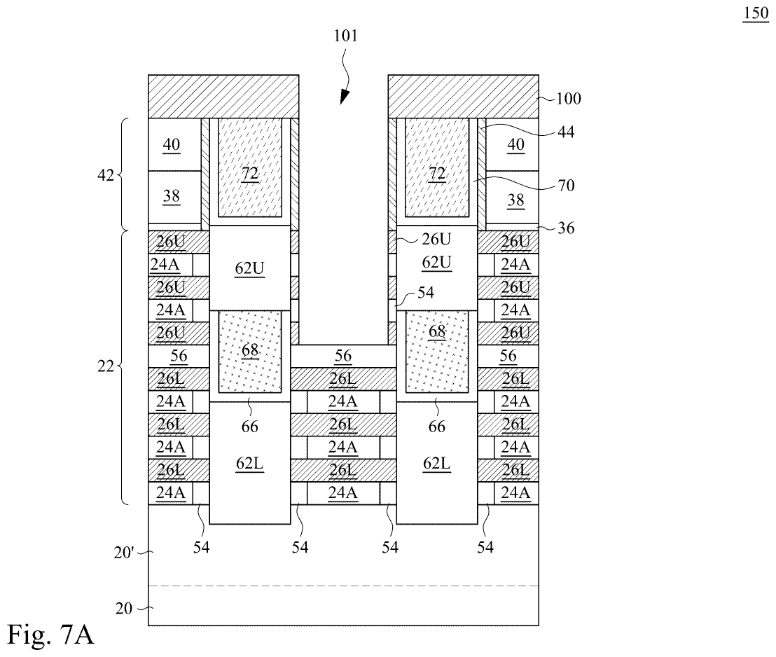

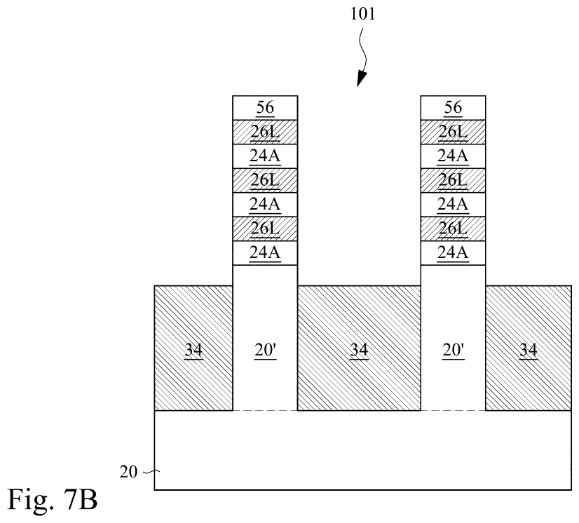

In FIGS. 7A and 7B, the opening 101 is extended by removing portions of the upper semiconductor nanostructures 26U, portions of the inner spacers 54, and the dummy nanostructures 24A to expose the dielectric isolation layer 56 underneath. FIG. 7A is a cross-sectional view corresponding to the cross-sectional view shown in FIG. 6A. FIG. 7B is a cross-sectional view corresponding to the cross-sectional view shown in FIG. 6B. Portions of the upper semiconductor nanostructures 26U and portions of the inner spacers 54 directly underneath the opening 101, as well as the dummy nanostructures 24A may be removed by one or more dry etching processes using chlorine or bromine based plasma as etchants. After the one or more dry etching processes, portions of the upper semiconductor nanostructures 26U and portions of the inner spacers 54 directly underneath the gate spacers 44 may remain on sidewalls of the neighboring upper epitaxial source/drain regions 62U and first CESLs 66. After the opening 101 is extended, sidewalls of the remaining portions of the upper semiconductor nanostructures 26U and the inner spacers 54, and a top surface of the dielectric isolation layer 56 are exposed.

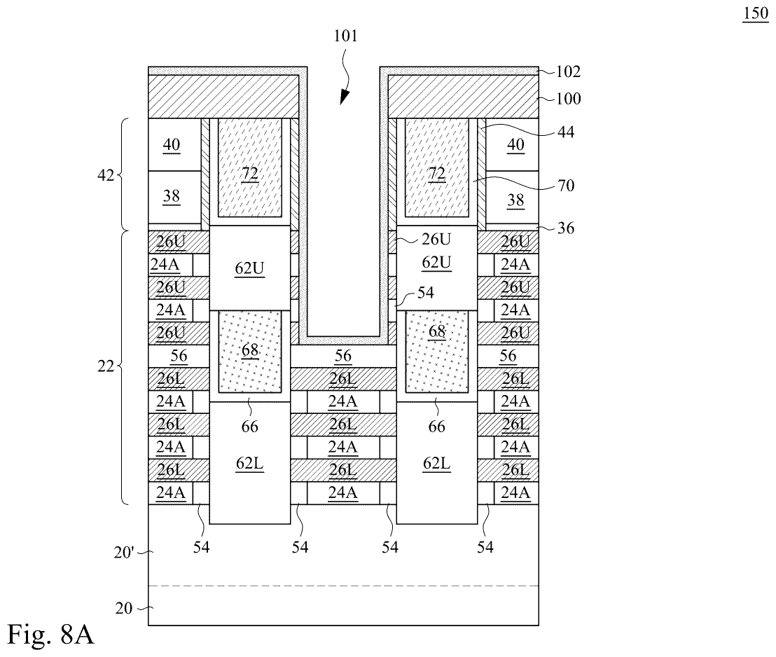

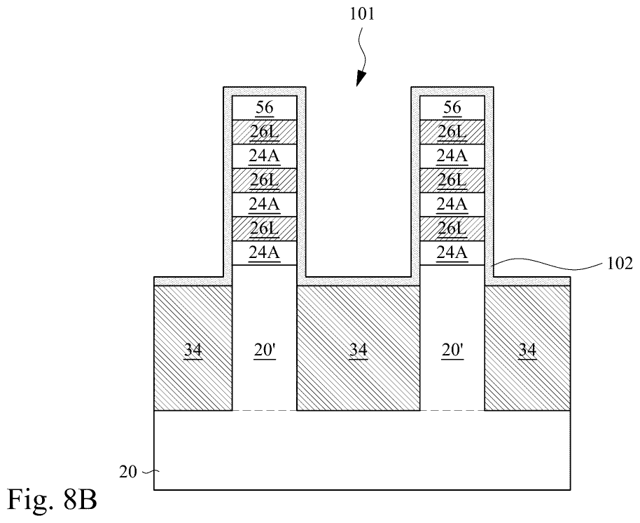

In FIGS. 8A and 8B, a dielectric liner 102 is formed in the opening 101. FIG. 8A is a cross-sectional view corresponding to the cross-sectional view shown in FIG. 7A. FIG. 8B is a cross-sectional view corresponding to the cross-sectional view shown in FIG. 7B. The dielectric liner 102 may be a conformal layer covering a top surface of the mask 100 and the surfaces exposed by the opening 101, which may include top surfaces of the dielectric isolation layer 56 and the STI regions 34, as well as sidewalls of the mask 100, the gate spacers 44, the remaining portions of the upper semiconductor nanostructures 26U and the inner spacers 54, the dielectric isolation layer 56, the lower semiconductor nanostructures 26L, the dummy nanostructures 24A, and the semiconductor fins 20'. As described in greater detail below, the dielectric liner 102 may provide protection to the mask 100 and the remaining portions of the inner spacers 54 during subsequent etching processes. The dielectric liner 102 may be formed of silicon nitride, silicon carbide, silicon carbonitride, aluminum oxide, titanium nitride, or the like. The dielectric liner 102 may be formed of a suitable deposition process, such as CVD, ALD, or the like.

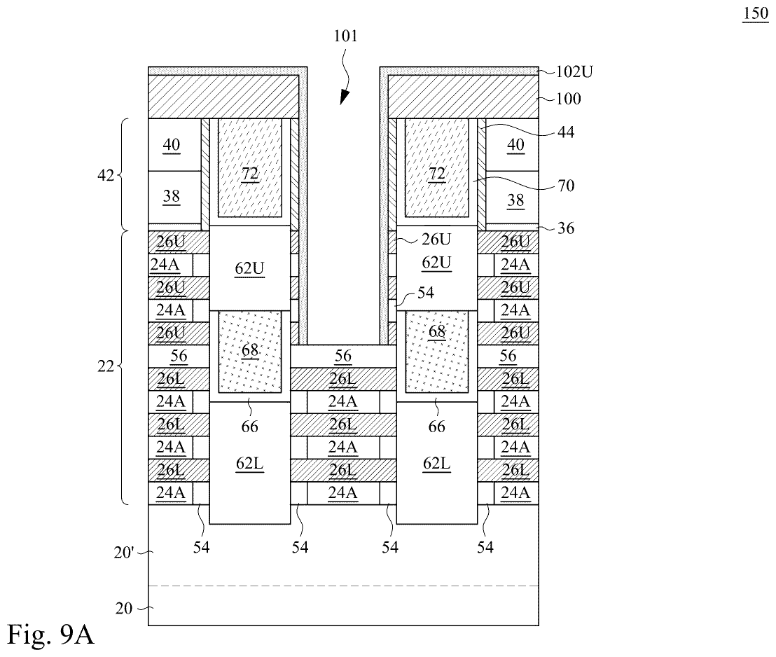

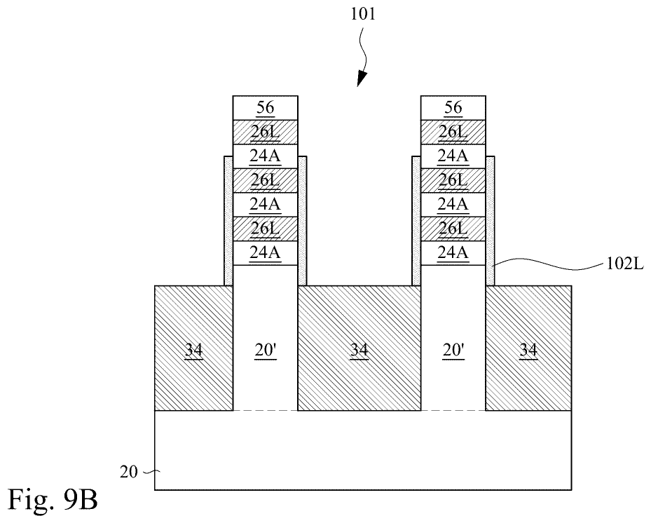

In FIGS. 9A and 9B, portions of the dielectric liner 102 are removed to partially expose the top surfaces of the dielectric isolation layer 56 and the STI regions 34. After the removal, the dielectric liner 102 may be separated into upper portions of the dielectric liner 102U and lower portions of the dielectric liner 102L. FIG. 9A is a cross-sectional view corresponding to the cross-sectional view shown in FIG. 8A. FIG. 9B is a cross-sectional view corresponding to the cross-sectional view shown in FIG. 8B. The portions of the dielectric liner 102 may be removed by a dry etching process using fluorine based plasma as etchants. The etching process may be an anisotropic etching process, which may remove horizontal portions of the dielectric liner 102 at a higher rate than the vertical portions of the dielectric liner 102. During the etching process, carbon based by-products of the plasma generation may concentrate at an upper portion of the opening 101, which may protect the portions of the dielectric liner 102 adjacent the mask 100 from the etchants. Vertical portions of the dielectric liner 102 adjacent the STI regions 34 may also be partially removed.

After the etching process, as shown in FIG. 9A, a portion of the top surface of the dielectric isolation layer 56 may be exposed, and the upper portions of the dielectric liner 102U may remain on the top surfaces of the mask 100 and the dielectric isolation layer 56, as well as on the sidewalls of the mask 100, the gate spacers 44, the remaining portions of the upper semiconductor nanostructures 26U and the inner spacers 54. After the etching process, as shown in FIG. 9B, portions of the top surfaces of the STI regions 34 may be exposed, the lower portions of the dielectric liner 102L may remain on the top surfaces of the STI regions 34, as well as on the sidewalls of the lower semiconductor nanostructures 26L, the dummy nanostructures 24A, and the semiconductor fins 20′.

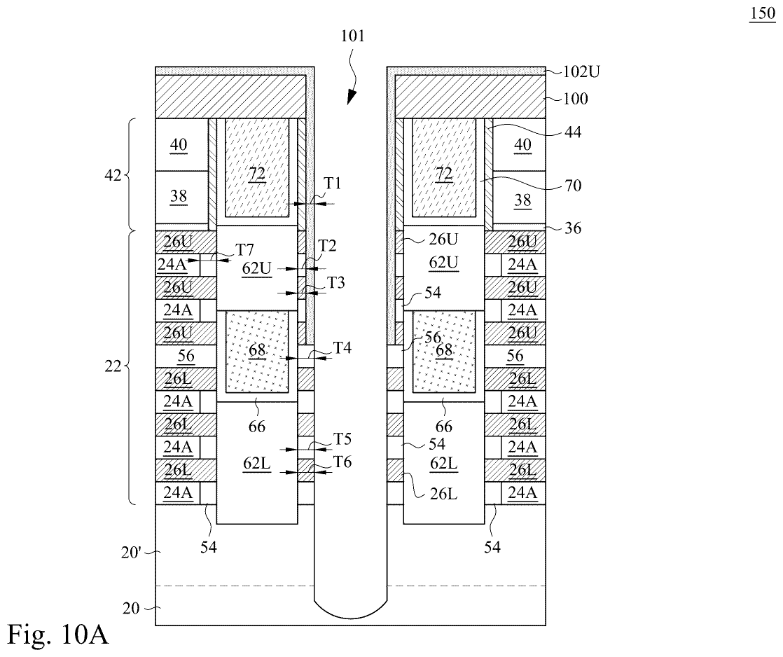

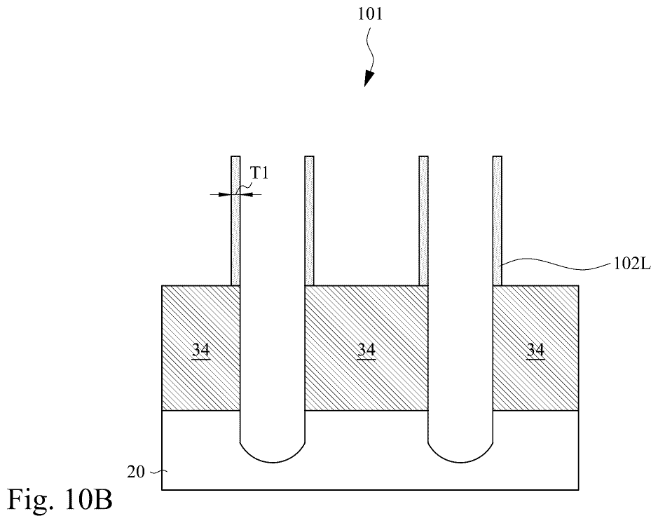

In FIGS. 10A and 10B, the opening 101 is further extended by removing portions of the dielectric isolation layer 56, portions of the lower semiconductor nanostructures 26L, the dummy nanostructures 24A, and the semiconductor fins 20′ to expose the substrate 20 underneath. Portions of the inner spacers 54 underneath the dielectric isolation layer 56 may also be removed. The opening 101 may have a curved bottom surface after the opening 101 is further extended. FIG. 10A is a cross-sectional view corresponding to the cross-sectional view shown in FIG. 9A. FIG. 10B is a cross-sectional view corresponding to the cross-sectional view shown in FIG. 9B. Portions of the dielectric isolation layer 56, portions of the lower semiconductor nanostructures 26L, and portions of the inner spacers 54 directly underneath the opening 101, as well as the dummy nanostructures 24A and the semiconductor fin 20′ may be removed by one or more dry etching processes using chlorine or bromine based plasma as etchants.

Due to the upper portions of the dielectric liner 102U on the sidewalls of the mask 100 and the remaining portions of the inner spacers 54, the mask 100 and the remaining portions of the inner spacers 54 may be sufficiently protected during the said etching processes, which may reduce the risk of damaging the neighboring upper epitaxial source/drain regions 62U, first CESLs 66, and second CESLs 70 during the said etching processes. As a result, the performance and reliability of the subsequently formed stacking transistor may be improved.

After the one or more dry etching processes, portions of the dielectric isolation layer 56, portions of the lower semiconductor nanostructures 26L, and portions of the inner spacers 54 directly underneath the gate spacers 44 and the upper portions of the dielectric liner 102U may remain on sidewalls of the neighboring lower epitaxial source/drain regions 62L and first CESLs 66. After the opening 101 is further extended, sidewalls of the remaining portions of the dielectric isolation layer 56, the lower semiconductor nanostructures 26L, and the inner spacers 54, sidewalls of the lower portions of the dielectric liner 102L, the STI regions 34, and the substrate 20, as well as an upper surface of the substrate 20 are exposed.

The upper portions of the dielectric liner 102U and the lower portions of the dielectric liner 102L may have a thickness T1 in a range from about 1 nm to about 2 nm. The remaining portions of the inner spacers 54 in contact with the remaining portions of the upper semiconductor nanostructures 26U may have a thickness T2 in a range from about 1.6 nm to about 2.4 nm. The remaining portions of the upper semiconductor nanostructures 26U may have a thickness T3 in a range from about 1.6 nm to about 2.4 nm. The remaining portions of the dielectric isolation layer 56 may have a thickness T4 in a range from about 2.4 nm to about 3.6 nm. The thickness T4 may be larger than the thickness T2. The remaining portions of the inner spacers 54 in contact with the remaining portions of the lower semiconductor nanostructures 26L may have a thickness T5 in a range from about 2.4 nm to about 3.6 nm. The remaining portions of the lower semiconductor nanostructures 26L may have a thickness T6 in a range from about 2.4 nm to about 3.6 nm. The thickness T5 may be larger than the thickness T2. The thickness T6 may be larger than the thickness T3. The intact inner spacers 54 in other multi-layer stacks 22 may have a thickness T7, which may be larger than the thickness T5 and the thickness T2.

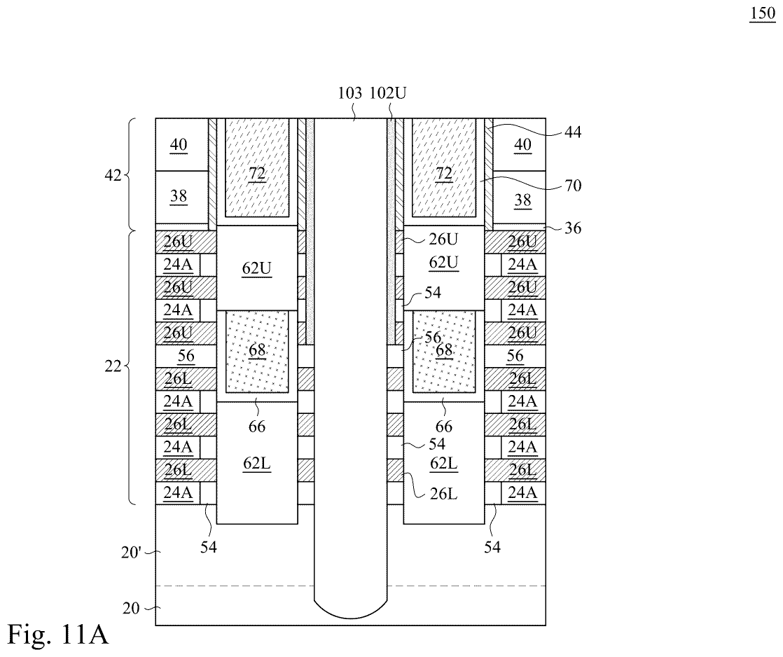

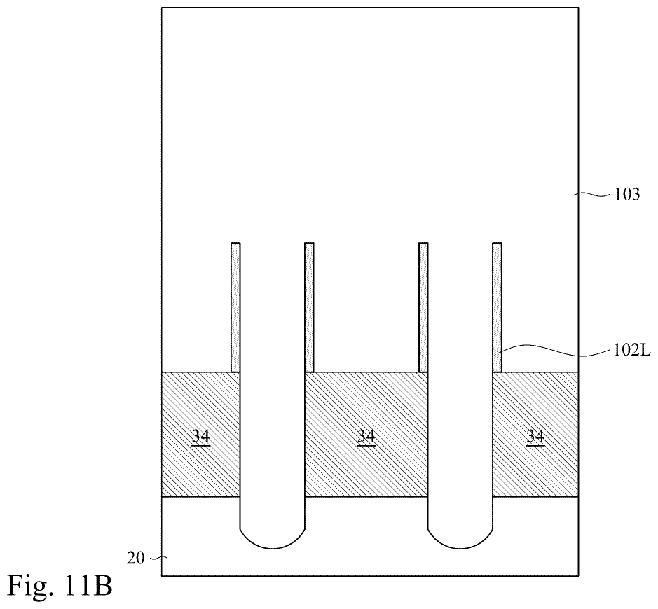

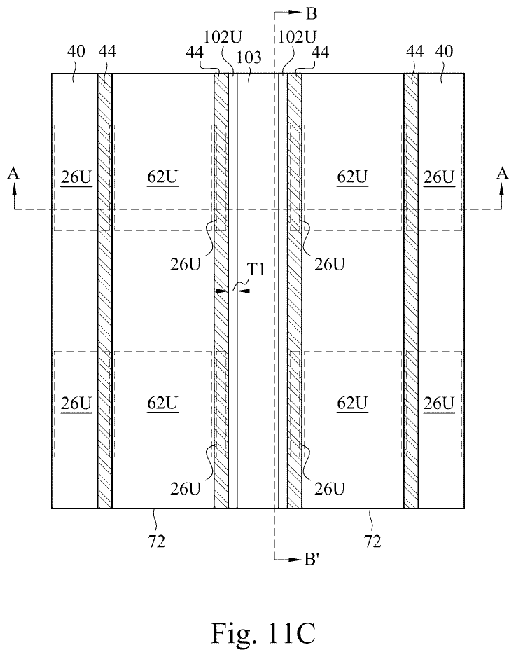

In FIGS. 11A, 11B, and 11C, an isolation feature 103 is formed in the opening 101, and the mask 100 and portions of the upper portions of the dielectric liner 102U are removed. FIG. 11C is a top-down view with certain features omitted and certain features shown in dashed lines for illustrative purposes. The reference cross-sections A-A′ and B-B′ shown in FIG. 11C may correspond to the reference cross-sections A-A′ and B-B′ shown in FIG. 6C. FIG. 11A is a cross-sectional view along the reference cross-section A-A′ as shown in FIG. 11C. FIG. 11B is a cross-sectional view along the reference cross-section B-B′ as shown in FIG. 11C. The isolation feature 103 may fill up the opening 101 and contact surfaces previously exposed by the opening 101. The sidewalls of the upper portions of the dielectric liner 102U may be covered by the isolation feature 103. The top surfaces and sidewalls of the lower portions of the dielectric liner 102L may be covered by the isolation feature 103.

The isolation feature 103 may be formed of one or more dielectric materials, such as silicon nitride, silicon oxide, or the like. In some embodiments, the isolation feature 103 and the dielectric liner 102 comprise different materials. In some embodiments, the isolation feature 103 and the dielectric liner 102 comprise a same material. In some embodiments, the isolation feature 103 comprises multiple layers different dielectric materials. The isolation feature 103 may be formed by one or more suitable deposition processes, such as CVD, ALD, or the like. A planarization process such as a CMP process, an etch-back process, combinations thereof, or the like, may be performed after the deposition process to remove excess deposited material(s), as well as the mask 100 and portions of the upper portions of the dielectric liner 102U on the mask 100. After the planarization process, the top surfaces of the mask 40, the gate spacers 44, the second CESLs 70, the second ILDs 72, the upper portions of the dielectric liner 102U, and the isolation feature 103 may be substantially coplanar (within process variations).

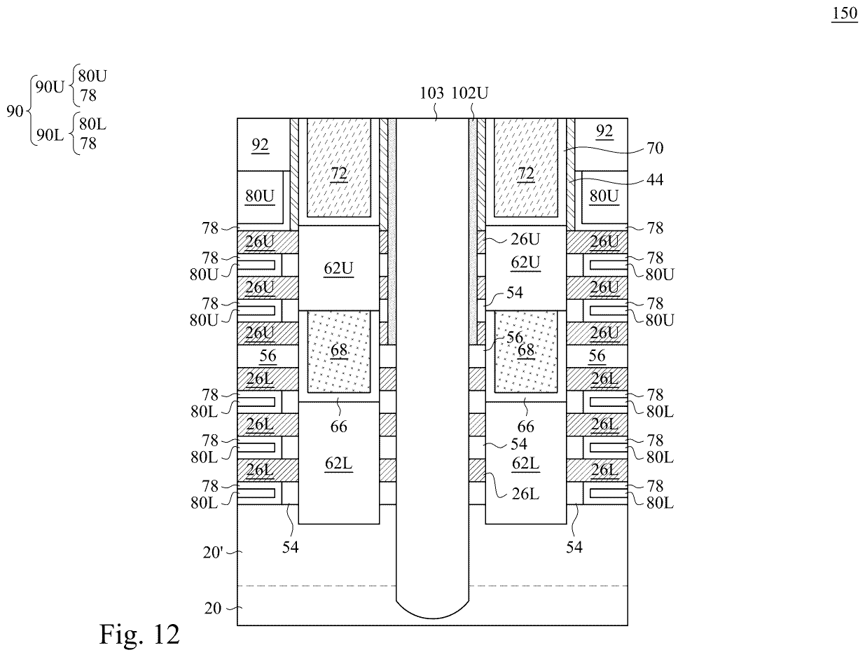

In FIG. 12, a gate replacement process to replace the dummy gate stacks 42 and the dummy nanostructures 24A with gate structures 90 is performed. The gate replacement process may include first removing the dummy gate stacks 42 and the dummy nanostructures 24A. The dummy gate stacks 42 may be removed by one or more suitable etching processes. The dummy nanostructures 24A may be then removed by an additional suitable etching process. The etching process that removes the dummy nanostructures 24A may selectively remove the material of the dummy nanostructures 24A without significantly removing the material(s) of the semiconductor nanostructures 26. In the embodiments where the dummy nanostructures 24A comprise silicon germanium, and the semiconductor nanostructures 26 comprise silicon, the etching process may be a wet isotropic etching process and etchants such as tetramethylammonium hydroxide, ammonium hydroxide, or the like may be used.

Then, gate dielectrics 78 may be deposited in the recesses between the gate spacers 44 and on the exposed semiconductor nanostructures 26. The gate dielectrics 78 may be conformally formed on the exposed surfaces of the recesses (the removed dummy gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor fins 20′; on the top surfaces, the sidewalls, and the bottom surfaces of the semiconductor nanostructures 26; and on the sidewalls of the inner spacers 54.

The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 may be illustrated, the gate dielectrics 78 may include multiple layers, such as an interfacial layer and an overlying high-k dielectric layer.

Lower gate electrodes 80L may be formed on the gate dielectrics 78 around the lower semiconductor nanostructures 26L. The lower gate electrodes 80L may wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material. The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

The lower gate electrodes 80L may be formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

In some embodiments, isolation layers (not illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Upper gate electrodes 80U may be formed on the isolation layers described above (if present) or the lower gate electrodes 80L. The upper gate electrodes 80U may be disposed between the upper semiconductor nanostructures 26U. In some embodiments, the upper gate electrodes 80U wrap around the upper semiconductor nanostructures 26U. The upper gate electrodes 80U may be formed of the same or similar materials and formed by same or similar processes as the lower gate electrodes 80L. The upper gate electrodes 80U may be formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered upper gate electrodes 80U are illustrated, the upper gate electrodes 80U may include any number of work function tuning layers, any number of barrier layers, any number of glue layers, and a fill material.

Gate masks 92 may be formed on the upper gate structures 90U. The formation process may include recessing the upper gate structures 90U, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72 and to level top surfaces of the gate masks 92 and the second ILD 72. The planarization process may be a CMP process, an etch-back process, combinations thereof, or the like. After the planarization process, the top surfaces of the gate masks 92, the gate dielectrics 78, the second ILD 72, and the gate spacers 44 may be substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

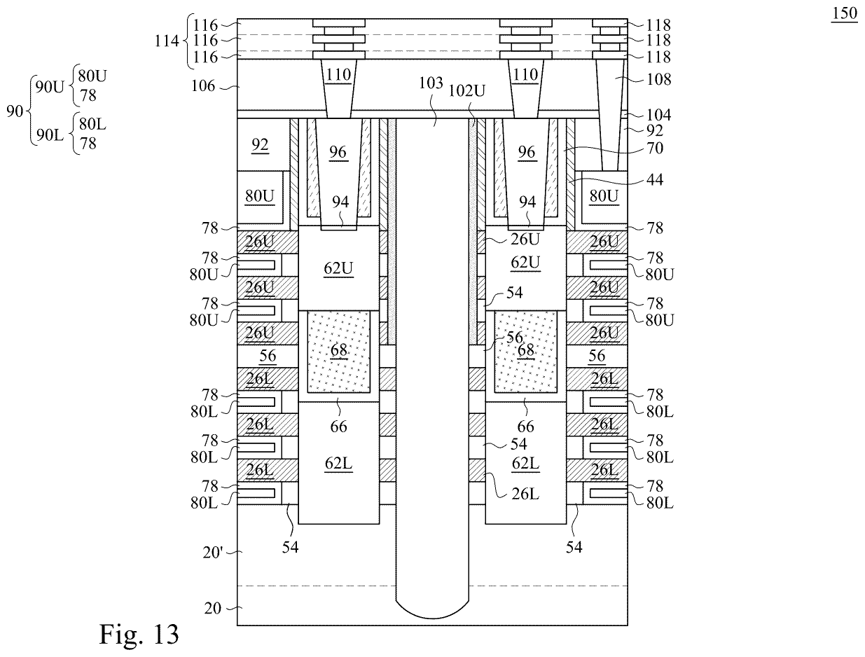

In FIG. 13, metal-semiconductor alloy regions 94 and source/drain contacts 96 are formed through the second ILD 72 to electrically couple to the upper epitaxial source/drain regions 62U and/or the lower epitaxial source/drain regions 62L. As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

A third CESL 104 and a third ILD 106 are then formed. In some embodiments, the third CESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the third CESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the third ILD 106. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate structures 90L and the lower epitaxial source/drain regions 62L may be made through a backside of the substrate 20 (e.g., a side opposite to the front-side interconnect structure 114). The structure shown in FIG. 13 may be referred to as a stacking transistor 150.

The embodiments of the present disclosure have some advantageous features. Due to the formation of the dielectric liner 102U, the mask 100 and the remaining portions of the inner spacers 54 covered by the dielectric liner 102U may be sufficiently protected during the etching processes which further extend the opening 101, which may reduce the risk of damaging the neighboring upper epitaxial source/drain regions 62U, first CESLs 66, and second CESLs 70 during the said etching processes. As a result, the performance and reliability of the stacking transistor 150 may be improved.

In an embodiment, a semiconductor device includes a first source/drain region; a first nanostructure on a first sidewall of the first source/drain region; a first gate structure around the first nanostructure; a first inner spacer on the first sidewall of the first source/drain region, wherein the first inner spacer is between the first gate structure and the first source/drain region; a second inner spacer on a second sidewall of the first source/drain region, wherein the second sidewall is opposite to the first sidewall; a first dielectric liner on a sidewall of the second inner spacer, wherein the second inner spacer is between the first dielectric liner and the first source/drain region; and a first isolation feature on a sidewall of the first dielectric liner, wherein the first dielectric liner is between the first isolation feature and the second inner spacer. In an embodiment, the first dielectric liner includes a first material, wherein the first isolation feature includes a second material different from the first material. In an embodiment, the semiconductor further includes a second isolation feature underneath the second inner spacer, wherein the first dielectric liner is on a top surface of the second isolation feature. In an embodiment, the second isolation feature and the second inner spacer include a same material. In an embodiment, the second inner spacer is thinner than the first inner spacer. In an embodiment, the semiconductor device further includes a second source/drain region underneath the first source/drain region; and a third inner spacer between the second source/drain region and the first isolation feature, wherein the second inner spacer is thinner than the third inner spacer. In an embodiment, the semiconductor device further includes a second isolation feature underneath the first source/drain region, wherein the first isolation feature extends into the second isolation feature; and a second dielectric liner on a top surface of the second isolation feature, wherein the first dielectric liner and the second dielectric liner include a same first material different from a second material of the first isolation feature, and wherein the first isolation feature is on a top surface and sidewalls of the second dielectric liner.

In an embodiment, a method of forming a semiconductor device includes forming a first nanostructure and a second nanostructure over the first nanostructure; growing a first source/drain region and a second source/drain region, wherein the first nanostructure is on a sidewall of the first source/drain region, and wherein the second nanostructure is on a sidewall of the second source/drain region; forming a first opening by removing a first portion of the second nanostructure, wherein a second portion of the second nanostructure remains on the sidewall of the second source/drain region; depositing a dielectric liner in the first opening, wherein the dielectric liner is on a sidewall of the second portion of the second nanostructure; extending the first opening by removing a first portion of the dielectric liner and a first portion of the first nanostructure, wherein a second portion of the dielectric liner remains on the sidewall of the second portion of the second nanostructure, and wherein a second portion of the first nanostructure remains on the sidewall of the first source/drain region; and depositing a first isolation feature in the first opening, wherein the first isolation feature is on a sidewall of the second portion of the dielectric liner, and wherein the first isolation feature is on a sidewall of the second portion of the first nanostructure. In an embodiment, the second portion of the first nanostructure has a larger thickness than the second portion of the second nanostructure. In an embodiment, the dielectric liner and the first isolation feature include different materials. In an embodiment, the dielectric liner is between the second portion of the second nanostructure and the first isolation feature. In an embodiment, the method further includes forming a second isolation feature between the first nanostructure and the second nanostructure before forming the first opening, wherein a top surface of the second isolation feature is exposed after forming the first opening. In an embodiment, the dielectric liner is deposited on the top surface of the second isolation feature. In an embodiment, extending the first opening further includes removing a first portion of the second isolation feature, and wherein the first isolation feature is on a sidewall of a second portion of the second isolation feature.

In an embodiment, a method of forming a semiconductor device includes forming a first nanostructure; forming a first inner spacer, wherein the first inner spacer is on a top surface of the first nanostructure; forming a first isolation feature underneath the first nanostructure; forming a first dielectric feature, wherein the first isolation feature is on a sidewall of the first dielectric feature; growing a first source/drain region over the first dielectric feature, wherein the first nanostructure and the first inner spacer are on a sidewall of the first source/drain region; forming a first opening by removing a first portion of the first nanostructure and a first portion of the first inner spacer, wherein a second portion of the first nanostructure and a second portion of the first inner spacer remain on the sidewall of the first source/drain region, and wherein a top surface of the first isolation feature is exposed by the first opening; depositing a dielectric liner in the first opening, wherein the dielectric liner is on a sidewall of the second portion of the first nanostructure, a sidewall of the second portion of the first inner spacer, and the top surface of the first isolation feature; extending the first opening by removing a first portion of the dielectric liner and a first portion of the first isolation feature, wherein a second portion of the dielectric liner remains on the sidewall of the second portion of the first nanostructure and the sidewall of the second portion of the first inner spacer, and wherein a second portion of the first isolation feature remains on the sidewall of the first dielectric feature; and depositing a second isolation feature in the first opening, wherein the second isolation feature is on a sidewall of the second portion of the dielectric liner, and wherein the second isolation feature is on a sidewall of the second portion of the first isolation feature. In an embodiment, the second portion of the first inner spacer is thinner than the second portion of the first isolation feature. In an embodiment, the second portion of the dielectric liner is on a top surface of the second portion of the first isolation feature. In an embodiment, the method further includes forming a second nanostructure before forming the first nanostructure, wherein the first isolation feature is between the first nanostructure and the second nanostructure; forming a second inner spacer, wherein the second inner spacer is on a top surface of the second nanostructure; and growing a second source/drain region before forming the first dielectric feature, wherein the second nanostructure and the second inner spacer are on a sidewall of the second source/drain region. In an embodiment, extending the first opening further includes removing a first portion of the second nanostructure and a first portion of the second inner spacer, and wherein a second portion of the second nanostructure and a second portion of the second inner spacer remain on the sidewall of the second source/drain region. In an embodiment, the second portion of the first inner spacer is thinner than the second portion of the second inner spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first source/drain region;
a first nanostructure on a first sidewall of the first source/drain region;
a first gate structure around the first nanostructure;
a first inner spacer on the first sidewall of the first source/drain region, wherein the first inner spacer is between the first gate structure and the first source/drain region;
a second inner spacer on a second sidewall of the first source/drain region, wherein the second sidewall is opposite to the first sidewall;
a first dielectric liner on a sidewall of the second inner spacer, wherein the second inner spacer is between the first dielectric liner and the first source/drain region; and
a first isolation feature on a sidewall of the first dielectric liner, wherein the first dielectric liner is between the first isolation feature and the second inner spacer.

2. The semiconductor device of claim 1, wherein the first dielectric liner comprises a first material, wherein the first isolation feature comprises a second material different from the first material.

3. The semiconductor device of claim 1, further comprising a second isolation feature underneath the second inner spacer, wherein the first dielectric liner is on a top surface of the second isolation feature.

4. The semiconductor device of claim 3, wherein the second isolation feature and the second inner spacer comprise a same material.

5. The semiconductor device of claim 1, wherein the second inner spacer is thinner than the first inner spacer.

6. The semiconductor device of claim 1, further comprising:
a second source/drain region underneath the first source/drain region; and
a third inner spacer between the second source/drain region and the first isolation feature, wherein the second inner spacer is thinner than the third inner spacer.

7. The semiconductor device of claim 1, further comprising:
a second isolation feature underneath the first source/drain region, wherein the first isolation feature extends into the second isolation feature; and
a second dielectric liner on a top surface of the second isolation feature, wherein the first dielectric liner and the second dielectric liner comprise a same first material different from a second material of the first isolation feature, and wherein the first isolation feature is on a top surface and sidewalls of the second dielectric liner.

8. A method of forming a semiconductor device, the method comprising:
forming a first nanostructure and a second nanostructure over the first nanostructure;
growing a first source/drain region and a second source/drain region, wherein the first nanostructure is on a sidewall of the first source/drain region, and wherein the second nanostructure is on a sidewall of the second source/drain region;
forming a first opening by removing a first portion of the second nanostructure, wherein a second portion of the second nanostructure remains on the sidewall of the second source/drain region;
depositing a dielectric liner in the first opening, wherein the dielectric liner is on a sidewall of the second portion of the second nanostructure;
extending the first opening by removing a first portion of the dielectric liner and a first portion of the first nanostructure, wherein a second portion of the dielectric liner remains on the sidewall of the second portion of the second nanostructure, and wherein a second portion of the first nanostructure remains on the sidewall of the first source/drain region; and
depositing a first isolation feature in the first opening, wherein the first isolation feature is on a sidewall of the second portion of the dielectric liner, and wherein the first isolation feature is on a sidewall of the second portion of the first nanostructure.

9. The method of claim 8, wherein the second portion of the first nanostructure has a larger thickness than the second portion of the second nanostructure.

10. The method of claim 8, wherein the dielectric liner and the first isolation feature comprise different materials.

11. The method of claim 8, wherein the dielectric liner is between the second portion of the second nanostructure and the first isolation feature.

12. The method of claim 8, further comprising forming a second isolation feature between the first nanostructure and the second nanostructure before forming the first opening, wherein a top surface of the second isolation feature is exposed after forming the first opening.

13. The method of claim 12, wherein the dielectric liner is deposited on the top surface of the second isolation feature.

14. The method of claim 13, wherein extending the first opening further comprises removing a first portion of the second isolation feature, and wherein the first isolation feature is on a sidewall of a second portion of the second isolation feature.

15. A method of forming a semiconductor device, the method comprising:
forming a first nanostructure;
forming a first inner spacer, wherein the first inner spacer is on a top surface of the first nanostructure;
forming a first isolation feature underneath the first nanostructure;
forming a first dielectric feature, wherein the first isolation feature is on a sidewall of the first dielectric feature;
growing a first source/drain region over the first dielectric feature, wherein the first nanostructure and the first inner spacer are on a sidewall of the first source/drain region;
forming a first opening by removing a first portion of the first nanostructure and a first portion of the first inner spacer, wherein a second portion of the first nanostructure and a second portion of the first inner spacer remain on the sidewall of the first source/drain region, and wherein a top surface of the first isolation feature is exposed by the first opening;
depositing a dielectric liner in the first opening, wherein the dielectric liner is on a sidewall of the second portion of the first nanostructure, a sidewall of the second portion of the first inner spacer, and the top surface of the first isolation feature;
extending the first opening by removing a first portion of the dielectric liner and a first portion of the first isolation feature, wherein a second portion of the dielectric liner remains on the sidewall of the second portion of the first nanostructure and the sidewall of the second portion of the first inner spacer, and wherein a second portion of the first isolation feature remains on the sidewall of the first dielectric feature; and
depositing a second isolation feature in the first opening, wherein the second isolation feature is on a sidewall of the second portion of the dielectric liner, and wherein the second isolation feature is on a sidewall of the second portion of the first isolation feature.

16. The method of claim 15, wherein the second portion of the first inner spacer is thinner than the second portion of the first isolation feature.

17. The method of claim 15, wherein the second portion of the dielectric liner is on a top surface of the second portion of the first isolation feature.

18. The method of claim 15, further comprising:
forming a second nanostructure before forming the first nanostructure, wherein the first isolation feature is between the first nanostructure and the second nanostructure;
forming a second inner spacer, wherein the second inner spacer is on a top surface of the second nanostructure; and
growing a second source/drain region before forming the first dielectric feature, wherein the second nanostructure and the second inner spacer are on a sidewall of the second source/drain region.

19. The method of claim 18, wherein extending the first opening further comprises removing a first portion of the second nanostructure and a first portion of the second inner spacer, and wherein a second portion of the second nanostructure and a second portion of the second inner spacer remain on the sidewall of the second source/drain region.

20. The method of claim 19, wherein the second portion of the first inner spacer is thinner than the second portion of the second inner spacer.
